(19) United States
(12) Patent Application Publication
(10) Pub. No.: US 2018/0316340 A1
(43) Pub. Date: Nov. 1, 2018

(54) VARIABLE THRESHOLD COMPENSATION VOLTAGE GENERATION

(71) Applicant: Cirrus Logic International Semiconductor Ltd., Edinburgh (GB)

(72) Inventors: Anuradha PARSI, Austin, TX (US); Michael A. KOST, Austin, TX (US); Aaron BRENNAN, Austin, TX (US)

(73) Assignee: Cirrus Logic International Semiconductor Ltd., Edinburgh (GB)

(21) Appl. No.: 15/925,377

(22) Filed: Mar. 19, 2018

Related U.S. Application Data
(60) Provisional application No. 62/490,186, filed on Apr. 26, 2017.

(51) Int. Cl. H03K 17/041; H03K 17/10; H03K 17/30

(52) U.S. Cl. CPC H03K 17/04106; H03K 2217/0054; H03K 17/302; H03K 17/102

(57) ABSTRACT

A circuit may include first circuitry within a lower voltage domain, second circuitry within a higher voltage domain, a pass gate switch coupled between the first circuitry and the second circuitry for selectively coupling the first circuitry to the second circuitry, and control circuitry configured to control and vary a control voltage of the pass gate switch based on a threshold voltage of the pass gate switch.

### RELATED APPLICATION

The present disclosure claims priority to U.S. Provisional Patent Application Ser. No. 62/490,186 filed Apr. 26, 2017, which is incorporated by reference herein in its entirety.

### FIELD OF DISCLOSURE

The present disclosure relates in general to circuits for electronic devices, including without limitation audio devices, including personal audio devices such as wireless telephones and media players, and more specifically, to systems and methods relating to providing and managing a control voltage for a switch.

### BACKGROUND

Electronic devices are prevalent and in everyday use. Electronic devices are often implemented in integrated circuit packages or “chips” with multiple pins for receiving and/or transmitting signals from/to the integrated circuit package.

One potential problem that may occur when an integrated circuit package is placed in a device is that a pin of an integrated circuit package may be electrically shorted to a supply voltage (e.g., 5.5 volts) of a voltage supply external to the integrated circuit package. Such electrical shorting may be problematic as a transmit driver for driving a signal on the pin may not be able to handle voltages as high as the external supply voltage, and thus must be protected from exposure to such external supply voltage.

FIG. 1 illustrate an example approach used to protect a transmit driver on an integrated circuit package, as is known in the art. As shown in FIG. 1, if a pin 10 is shorted to an external voltage supply 12, a transmitter driver 14 for driving pin 10 having an internal voltage supply 16 with an internal supply voltage (e.g., 1.2 volts) lower than that of an external supply voltage (e.g., 5.5 volts) of external voltage supply 12 may be protected by a switch 18 driven by a low drop out regulator (LDO) 19 (or other suitable device for generating a control voltage) configured to generate a control voltage V_{G} for the gate of switch 18. In some instances, switch 18 is implemented using a lateral diffusion metal-oxide-semiconductor switch, as is known in the art. Thus, when pin 10 is shorted to external voltage supply 12, LDO 19 may drive a ground voltage (e.g., 0 volts) to the gate of switch 18 to decouple pin 10 from transmitter driver 14 to protect transmitter driver 14. However, when pin 10 is not shorted to external voltage supply 12 and it is desired that transmitter driver 14 drive pin 10, LDO 19 may drive a sufficiently high voltage (e.g., greater than a threshold voltage of switch 18) to couple the output of transmitter driver 14 to pin 10.

One drawback with this approach is that a threshold voltage of switch 18 may vary with temperature, process, aging, and/or other effects. Accordingly, dimensions of switch 18 may need to be designed for a worst-case scenario for the threshold voltage of switch 18, which may require relatively large switch sizes to account for the possibility of worst-case operation, which have the disadvantages of taking up valuable package space, being potentially more costly, and possibly requiring greater power for operation.

### SUMMARY

In accordance with the teachings of the present disclosure, one or more disadvantages and problems associated with providing and managing a switch control voltage may be reduced or eliminated.

In accordance with embodiments of the present disclosure, a circuit may include first circuitry within a lower voltage domain, second circuitry within a higher voltage domain, a pass gate switch coupled between the first circuitry and the second circuitry for selectively coupling the first circuitry to the second circuitry, and control circuitry configured to control and vary a control voltage of the pass gate switch to compensate for variation of a threshold voltage of the pass gate switch.

In accordance with these and other embodiments of the present disclosure, a method may be provided for use in a circuit having first circuitry within a lower voltage domain, second circuitry within a higher voltage domain, and a pass gate switch coupled between the first circuitry and the second circuitry for selectively coupling the first circuitry to the second circuitry. The method may include controlling and varying a control voltage of the pass gate switch to compensate for variation of a threshold voltage of the pass gate switch.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an example approach used to protect a transmit driver on an integrated circuit package, as is known in the art;

FIG. 2 illustrates a circuit diagram of a circuit comprising first circuitry within a lower voltage domain, second circuitry within a higher voltage domain, a pass gate switch coupled between the first circuitry and the second circuitry, and control circuitry configured to control and vary a control voltage of the pass gate switch based on a threshold voltage of the pass gate switch, in accordance with embodiments of the present disclosure;

FIG. 3 illustrates a circuit diagram of a circuit functionally equivalent to the circuit depicted in FIG. 2, in accordance with embodiments of the present disclosure;

FIG. 4 illustrates a circuit diagram of a circuit in accordance with that shown in FIG. 2, showing example components for implementing control circuitry of the circuit of FIG. 2, in accordance with embodiments of the present disclosure;

FIG. 5 illustrates a circuit diagram of a circuit functionally equivalent to the circuit depicted in FIG. 4, in accordance with embodiments of the present disclosure;

FIGS. 6A and 6B illustrate circuit diagrams of transistors implemented with a plurality of unit transistor elements, in accordance with embodiments of the present disclosure;

FIG. 7 illustrates a circuit diagram of a circuit in accordance with that shown in FIG. 2, showing example components for implementing control circuitry of the circuit of FIG. 2, in accordance with embodiments of the present disclosure;

FIG. 8 illustrates a circuit diagram of a circuit functionally equivalent to the circuit depicted in FIG. 7, in accordance with embodiments of the present disclosure; and

FIG. 9 illustrates a circuit diagram of a circuit in accordance with that shown in FIG. 2, showing example components for implementing control circuitry of the circuit of FIG. 2, in accordance with embodiments of the present disclosure.

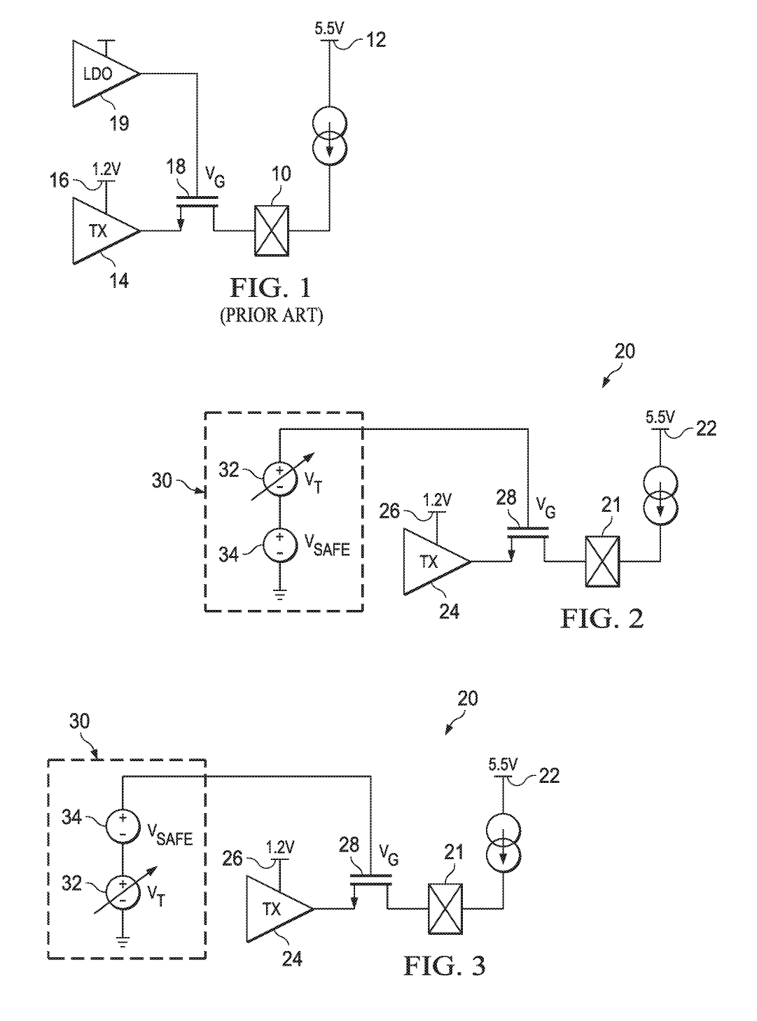

### DETAILED DESCRIPTION

In accordance with embodiments of the present disclosure, shortcomings of existing approaches to generating a switch control voltage for protecting first circuitry within a lower voltage domain (e.g., a transmitter driver) from second circuitry within a higher voltage domain (e.g., an external supply voltage) may be overcome by using a pass gate switch coupled between the first circuitry and the second circuitry for selectively coupling the first circuitry to the second circuitry and control circuitry configured to control and vary a control voltage of the pass gate switch based on a threshold voltage of the pass gate switch.

FIG. 2 illustrates a circuit diagram of a circuit 20 comprising first circuitry within a lower voltage domain (e.g., a transmitter driver 24 driven from internal voltage supply 26), second circuitry within a higher voltage domain (e.g., external supply voltage 22 having a higher voltage than that of internal voltage supply 26), a pass gate switch 28 coupled between the first circuitry and the second circuitry (e.g., coupled to external supply voltage 22 via pin 21), and control circuitry 30 configured to control and vary a control voltage V_{G} of pass gate switch 28 based on a threshold voltage of pass gate switch 28, as described in more detail below.

Although FIG. 2 (and other figures described below) depict shorting pin 21 to external supply voltage 22 via a current source, those skilled in the art will recognize that a resistive conducting mechanism may be coupled between pin 21 and external supply voltage 22.

Pass gate switch 28 may include any suitable switching device for selectively electrically coupling and decoupling the first circuitry and the second circuitry based on control voltage V_{G} of pass gate switch 28. In other words, control circuitry 30 may vary control voltage V_{G} of pass gate switch 28 to selectively couple and decouple the first circuitry and the second circuitry (e.g., control circuitry 30 may set control voltage V_{G} of pass gate switch 28 to a ground voltage to decouple the first circuitry from the second circuitry). In some embodiments, pass gate switch 28 may comprise an n-type metal-oxide-semiconductor field-effect transistor. In such embodiments, pass gate switch 28 may comprise a lateral diffusion metal-oxide-semiconductor switch.

As shown in FIG. 2, control circuitry 30 may include a fixed voltage source 34 for generating a fixed voltage V_{SAFE} in series with a variable voltage source 32 for generating a variable voltage V_{T}, such that control voltage V_{G} of pass gate switch 28 equals the sum of fixed voltage V_{SAFE} and variable voltage V_{T}. Although FIG. 2 depicts fixed voltage source 34 coupled between a ground voltage and variable voltage source 32, and variable voltage source 32 coupled between fixed voltage source 34 and the gate of pass gate switch 28, the arrangement of fixed voltage source 34 and variable voltage source 32 may be reversed as shown in FIG. 3, resulting in a functionally equivalent circuit to that of FIG. 2 wherein variable voltage source 32 is coupled between a ground voltage and fixed voltage source 34 and fixed voltage source 34 is coupled between variable voltage source 32 and the gate of pass gate switch 28.

As described in greater detail below, variable voltage source 32 may comprise any combination of electrical and/or electronic components configured to generate a variable voltage V_{T} that varies in accordance with variance of the threshold voltage of pass gate switch 28. In addition, fixed voltage source 34 may comprise any combination of electrical and/or electronic components configured to generate a substantially fixed voltage V_{SAFE} that remains constant despite variance of the threshold voltage of pass gate switch 28. In some embodiments, voltage V_{SAFE} generated by fixed voltage source 34 may be set based on a known safe maximum voltage for the output of transmitter driver 24. Various examples of variable voltage source 32 and fixed voltage source 34 are described in greater detail below.

In operation, variable voltage source 32 may vary its variable voltage VT in proportion to a variance of a threshold voltage of pass gate switch 28. Accordingly, control circuitry 30 may vary control voltage V_{G} of pass gate switch 28 to compensate for a variance of the threshold voltage of pass gate switch 28 due to one or more of temperature, process, and aging of pass gate switch 28.

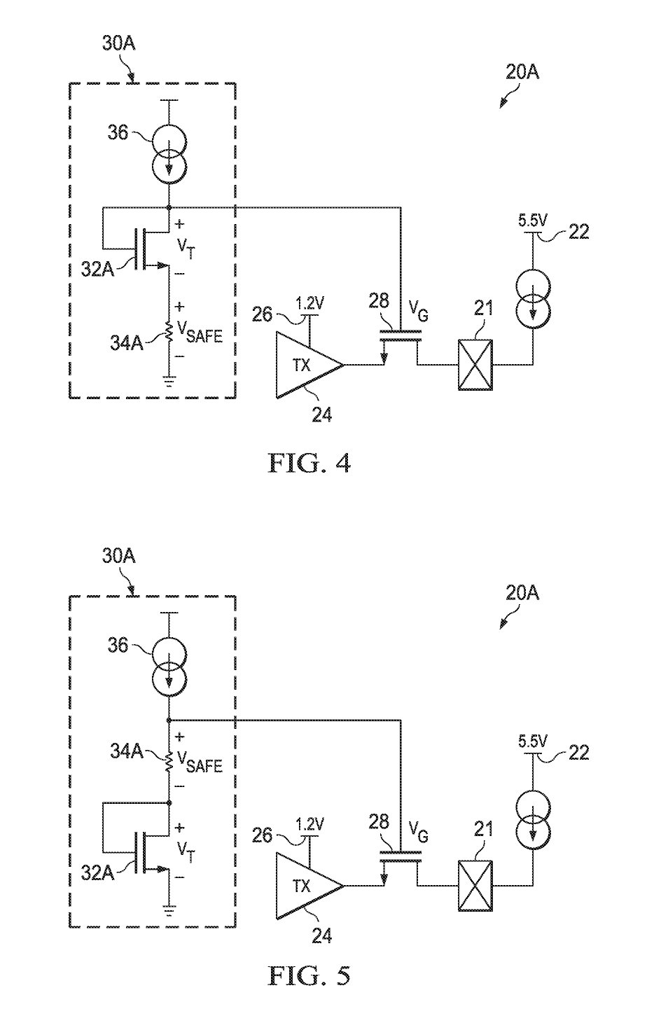

FIG. 4 illustrates a circuit diagram of a circuit 20A which depicts example control circuitry 30A for implementing control circuitry 30 of circuit 20 of FIG. 2, in accordance with embodiments of the present disclosure. As shown in FIG. 4, control circuitry 30A may comprise a transistor 32A to implement variable voltage source 32 of circuit 20 and may comprise a resistor 34A driven by a current source 36 to implement fixed voltage source 34. As depicted in FIG. 4, transistor 32A may comprise an n-type metal-oxide-semiconductor field effect transistor wherein transistor 32A is configured in a diode-connected configuration such that the drain terminal of transistor 32A is connected to the gate terminal of transistor 32A. As so configured, in operation, transistor 32A may generate variable voltage V_{T} between its drain terminal and its source terminal, wherein variable voltage V_{T} is equal to a threshold voltage of transistor 32A, which threshold voltage may vary due to temperature, process, aging, and/or other factors. Further, resistor 34A may generate substantially fixed voltage V_{SAFE} which may be defined, in accordance with Ohm's law, by a resistance of resistor 34A and a current generated by current source 36 and flowing through resistor 34A.

Although FIG. 4 depicts resistor 34A coupled between a ground voltage and a source terminal of transistor 32A, and transistor 32A coupled between resistor 34A and current source 36, the arrangement of resistor 34A and transistor 32A may be reversed as shown in FIG. 5, resulting in a functionally equivalent circuit to that of FIG. 4 wherein transistor 32A is coupled between a ground voltage and resistor 34A, and resistor 34A is coupled between the drain terminal of transistor 32A and current source 36.

In some embodiments of circuit 20A depicted in FIGS. 4 and 5, pass gate switch 28 and transistor 32A may comprise the same type of transistor, such that the threshold voltage of transistor 32A (which may be equal to variable voltage V_{T}) tracks the threshold voltage of pass gate switch 28. For example, pass gate switch 28 and transistor 32A may comprise the same type of transistor in that both may comprise an n-type metal-oxide-semiconductor field-effect transistor. As used herein, same “type” denotes that two transistors are fabricated using a similar or identical process and operate under the same principle of operation.

In these and other embodiments, transistor 32A and pass gate switch 28 may be fabricated such that the threshold voltage of transistor 32A is approximately equal to the threshold voltage of pass gate switch 28. For example, such approximate equivalence of threshold voltages may be accomplished by fabricating transistor 32A and pass gate switch 28 as the same type of transistor, having approximately the same physical dimensions, and fabricated on the same semiconductor die. If so fabricated, it may be expected that both transistor 32A and pass gate switch 28 should experience substantially identical variances in their respective threshold voltages based on variations in temperature, process, aging, and/or other factors.

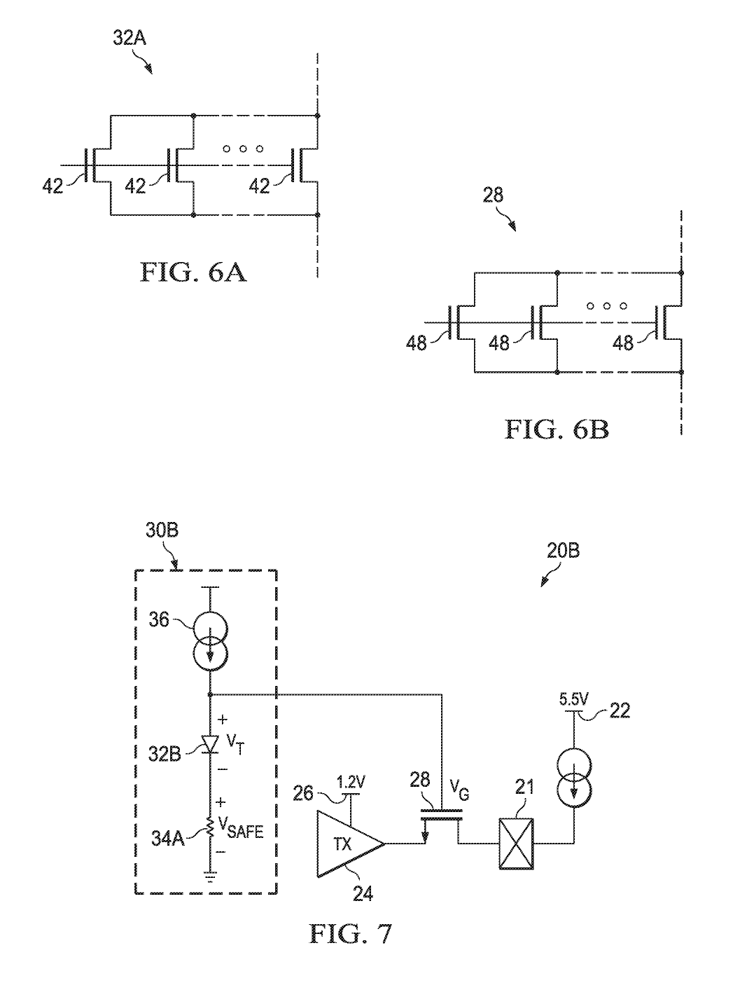

In some embodiments, one or both of transistor 32A and pass gate switch 28 may be implemented using a number of unit transistor elements. FIG. 6A illustrates a circuit diagram of transistor 32A implemented with a plurality of unit transistor elements 42 and FIG. 6B illustrates a circuit diagram of pass gate switch 28 implemented with a plurality of unit transistor elements 48, in accordance with embodiments of the present disclosure. For example, as shown in FIG. 6A, transistor 32A may be implemented with a plurality of parallel-connected unit transistor elements 42. In these and other embodiments, transistor 32A may be implemented in full or in part with a plurality of unit transistor elements 42, including any suitable combination of series-connected and parallel connected unit transistor elements 42. Similarly, as shown in FIG. 6B, pass gate switch 28 may be implemented with a plurality of parallel-connected unit transistor elements 48. In these and other embodiments, pass gate switch 28 may be implemented in full or in part with a plurality of unit transistor elements 48, including any suitable combination of series-connected and parallel connected unit transistor elements 48. As used herein, a “unit transistor element,” may represent, with respect to a particular fabrication and/or design process, a representative sized transistor defined by a designer, fabricator, or other maker of a circuit as a unit which may be replicated as needed to generate functional transistors comprising a plurality of unit transistor elements. Accordingly, pass gate switch 28 may comprise a first number of unit transistor elements 48 and transistor 32A may comprise a second number of unit transistor elements 42, wherein the first number and the second number may be equal or different. In some embodiments, a unit transistor element 48 may have physical dimensions approximately equal to that of a unit transistor element 42.

FIG. 7 illustrates a circuit diagram of a circuit 20B which depicts example control circuitry 30B for implementing control circuitry 30 of circuit 20 of FIG. 2, in accordance with embodiments of the present disclosure. As shown in FIG. 7, control circuitry 30B may comprise a diode 32B to implement variable voltage source 32 of circuit 20 and may comprise a resistor 34A driven by a current source 36 to implement fixed voltage source 34. Accordingly, control circuitry 30B of FIG. 7 may be identical to control circuitry 30A of FIG. 4, except that diode 32B is used in lieu of transistor 32A. As so configured, in operation, diode 32B may generate variable voltage V_{T} between its anode terminal and its cathode terminal, wherein variable voltage V_{T} is equal to a threshold voltage of diode 32B, which threshold voltage may vary due to temperature, process, aging, and/or other factors. Further, resistor 34A may generate substantially fixed voltage V_{SAFE} which may be defined, in accordance with Ohm's law, by a resistance of resistor 34A and a current generated by current source 36 and flowing through resistor 34A.

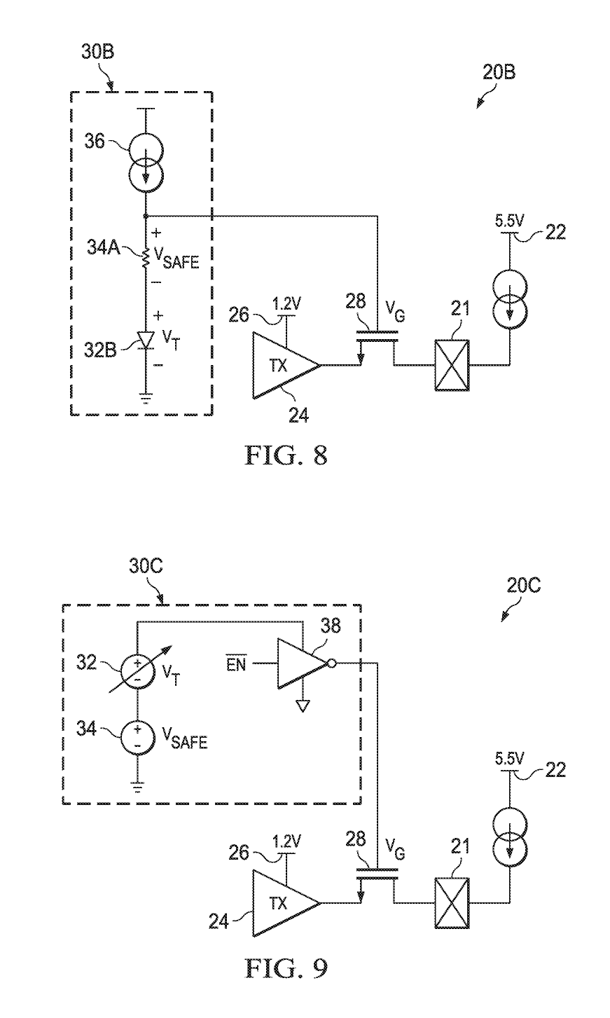

Although FIG. 7 depicts resistor 34A coupled between a ground voltage and a cathode terminal of diode 32B, and diode 32B coupled between resistor 34A and current source 36, the arrangement of resistor 34A and diode 32B may be reversed as shown in FIG. 8, resulting in a functionally equivalent circuit to that of FIG. 7 wherein diode 32B is coupled between a ground voltage and resistor 34A, and fixed resistor 34A is coupled between an anode terminal of diode 32B and current source 36.

FIG. 9 illustrates a circuit diagram of a circuit 20C which depicts example control circuitry 30C for implementing control circuitry 30 of circuit 20 of FIG. 2, in accordance with embodiments of the present disclosure. As shown in FIG. 9, control circuitry 30C may include a fixed voltage source 34 for generating a fixed voltage V_{SAFE} in series with a variable voltage source 32 for generating a variable voltage V_{T}, such that the sum of fixed voltage V_{SAFE} and variable voltage V_{T} is used as a supply voltage for an inverter 38, wherein pass gate switch 28 is selectively enabled or disabled by a control signal E̅N̅. Although FIG. 9 depicts fixed voltage source 34 coupled between a ground voltage and variable voltage source 32, and variable voltage source 32 coupled between fixed voltage source 34 and a supply input of inverter 38, the arrangement of fixed voltage source 34 and variable voltage source 32 may be reversed similarly to that shown in FIG. 3, resulting in a functionally equivalent circuit to that of FIG. 9 wherein variable voltage source 32 is coupled between a ground voltage and fixed voltage source 34, and fixed voltage source 34 is coupled between variable voltage source 32 and the supply input of inverter 38. In operation, variable voltage source 32 may vary its variable voltage VT in proportion to a variance of a threshold voltage of pass gate switch 28. Accordingly, control circuitry 30C may vary control of the supply voltage of inverter 38 which drives pass gate switch 28 to compensate for a variance of the threshold voltage of pass gate switch 28 due to one or more of temperature, process, and aging of pass gate switch 28.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

What is claimed is:

1. A circuit comprising:
first circuitry within a lower voltage domain;
second circuitry within a higher voltage domain;
a pass gate switch coupled between the first circuitry and the second circuitry for selectively coupling the first circuitry to the second circuitry; and
control circuitry configured to control and vary a control voltage of the pass gate switch to compensate for variation of a threshold voltage of the pass gate switch.

2. The circuit of claim 1, wherein:
the pass gate switch comprises a first transistor of a type; and
the control circuitry comprises a second transistor of the type, such that a second threshold voltage of the second transistor tracks the threshold voltage of the pass gate switch.

3. The circuit of claim 2, further wherein the second threshold voltage is approximately equal to the threshold voltage of the pass gate switch.

4. The circuit of claim 2, further wherein the second transistor has physical dimensions approximately equal to that of the first transistor.

5. The circuit of claim 2, further wherein the type is an n-type metal-oxide-semiconductor field effect transistor.

6. The circuit of claim 2, further wherein a drain terminal of the second transistor is connected to a gate terminal of the second transistor.

7. The circuit of claim 6, wherein a source terminal of the second transistor is coupled to a voltage source.

8. The circuit of claim 7, wherein the voltage source comprises a resistor wherein a voltage of the voltage source is defined by a resistance of the resistor and a current flowing through the resistor.

9. The circuit of claim 6, wherein the drain terminal of the second transistor is coupled to a voltage source.

10. The circuit of claim 2, further wherein:
the first transistor comprises a first number of first unit transistor elements; and
the second transistor comprises a second number of second unit transistor elements.

11. The circuit of claim 10, further wherein the first number and the second number are unequal.

12. The circuit of claim 10, wherein the first unit transistor elements have physical dimensions approximately equal to that of the second unit transistor elements.

13. The circuit of claim 1, wherein the control circuitry comprises a diode having a second threshold voltage that varies in proportion to a variance of the threshold voltage of the pass gate switch.

14. The circuit of claim 1, wherein the control circuitry comprises a variable voltage source that varies in proportion to a variance of the threshold voltage of the pass gate switch.

15. The circuit of claim 1, wherein the control circuitry varies the control voltage of the pass gate switch to compensate for a variance of the threshold voltage of the pass gate switch due to at least one of temperature and process of the pass gate switch.

16. The circuit of claim 1, wherein the control circuitry varies the control voltage to selectively couple and decouple the first circuitry and the second circuitry.

17. The circuit of claim 16, wherein the control circuitry sets the control voltage to a ground voltage to decouple the first circuitry and the second circuitry.

18. A method comprising, in a circuit having first circuitry within a lower voltage domain, second circuitry within a higher voltage domain, and a pass gate switch coupled between the first circuitry and the second circuitry for selectively coupling the first circuitry to the second circuitry:
controlling and varying a control voltage of the pass gate switch to compensate for variation of a threshold voltage of the pass gate switch.

19. The method of claim 18, wherein:
the pass gate switch comprises a first transistor of a type; and
control circuitry comprises a second transistor of the type, such that a second threshold voltage of the second transistor tracks the threshold voltage of the pass gate switch.

20. The method of claim 19, further wherein the second threshold voltage is approximately equal to the threshold voltage of the pass gate switch.

21. The method of claim 19, further wherein the second transistor has physical dimensions approximately equal to that of the first transistor.

22. The method of claim 19, further wherein the type is an n-type metal-oxide-semiconductor field effect transistor.

23. The method of claim 19, further wherein a drain terminal of the second transistor is connected to a gate terminal of the second transistor.

24. The method of claim 23, wherein a source terminal of the second transistor is coupled to a voltage source.

25. The method of claim 24, wherein the voltage source comprises a resistor wherein a voltage of the voltage source is defined by a resistance of the resistor and a current flowing through the resistor.

26. The method of claim 23, wherein the drain terminal of the second transistor is coupled to a voltage source.

27. The method of claim 19, further wherein:
the first transistor comprises a first number of first unit transistor elements; and
the second transistor comprises a second number of second unit transistor elements.

28. The method of claim 27, further wherein the first number and the second number are unequal.

29. The method of claim 27, wherein the first unit transistor elements have physical dimensions approximately equal to that of the second unit transistor elements.

30. The method of claim 18, wherein controlling and varying the control voltage comprises varying a second threshold voltage of a diode in proportion to a variance of the threshold voltage of the pass gate switch.

31. The method of claim 18, wherein controlling and varying the control voltage comprises varying a variable voltage source proportional to a variance of the threshold voltage of the pass gate switch.

32. The method of claim 18, further comprising varying the control voltage of the pass gate switch to compensate for a variance of the threshold voltage of the pass gate switch due to at least one of temperature and process of the pass gate switch.

33. The method of claim 18, further comprising varying the control voltage to selectively couple and decouple the first circuitry and the second circuitry.

34. The method of claim 33, further comprising setting the control voltage to a ground voltage to decouple the first circuitry and the second circuitry.
